(19) United States
(12) Patent Application Publication
(10) Pub. No.: US 2004/0261836 A1
(43) Pub. Date: Dec. 30, 2004

(54) Solar cell module and solar cell module array

(75) Inventors: Ichiro Kataoka, Nara (JP); Hidehisa Makita, Kyoto (JP); Masaaki Matsushita, Nara (JP); Takaaki Mukai, Nara (JP); Shigenori Itoyama, Nara (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/822,716

(22) Filed: Apr. 13, 2004

(30) Foreign Application Priority Data
Apr. 17, 2003 (JP) 2003-112284 (PAT.

(51) Int. Cl. H01L 25/00

(52) U.S. Cl. 136/244; 136/251

(57) ABSTRACT

A solar cell module is provided which comprises a solar cell element, and a front surface member provided so as to cover a light incidence surface of the solar cell element to provide an outermost surface of the solar cell module, wherein the front surface member comprises a fluoride polymer film having a light incidence surface subjected to a discharge treatment and which is, therefore, hard to stain even when placed outdoors for a long period of time, whereby it is possible to suppress a lowering in output caused by a decrease in quantity of incident light due to staining.

### BACKGROUND OF THE INVENTION

1. Field of the Invention

The present invention relates to a solar cell module, in particular, a solar cell module whose light incidence surface is coated with a fluoride polymer film and to a solar cell module array using the same.

2. Related Background Art

There are various forms of solar cells. Representative examples are crystalline silicon solar cells, polycrystalline silicon solar cells, thin film crystalline solar cells, microcrystalline silicon solar cells, amorphous silicon solar cells, copper indium selenide solar cells, and compound semiconductor solar cells. Of these solar cells, thin film solar cells, such as thin film crystalline solar cells, microcrystalline silicon solar cells, amorphous silicon solar cells and copper indium selenide solar cells, have the advantage that their area can be increased at a relatively low cost and they require only small amounts of raw materials. Thus research and development on them are being actively conducted in many different fields.

The thin film solar cells are formed on a substrate, for example, a glass, ceramic, or stainless steel sheet or a resin film, and use of a stainless steel sheet or resin film as a substrate provides a solar cell module light in weight and excellent in impact resistance as well as flexibility. However, unlike the case where an optically active semiconductor layer is deposited on a glass substrate and the glass substrate is used as a light incidence surface, in a solar cell module using a stainless steel sheet or resin film as a substrate, it is necessary to cover the light incidence surface with a transparent covering material to protect the solar cells. In these circumstances, there have been proposed solar cell modules light in weight and excellent in flexibility in which the characteristics of thin film solar cells are made full use of by employing a transparent fluoride polymer film, such as a fluorine resin film, as a front surface member and a various kind of transparent thermoplastic organic resin as an encapsulating material inside the front surface member. The reasons for the use of such materials are, for example, that: 1) fluoride polymer is excellent in weather resistance and water repellency, thereby being capable of reducing the lowering in output of the solar cell module which is caused by the decrease in light transmittance due to yellowing/opaqueness resulting from deterioration of the resin or due to staining of the resin surface; and 2) transparent thermoplastic resins are inexpensive, thereby being used in large amounts as an encapsulating material for protecting the photovoltaic elements disposed inside the solar cell module. In addition, on the solar cell elements are generally provided various current collecting electrodes for efficiently taking out a generated electric power and metal members for arranging the solar cell elements in series or parallel, and transparent thermoplastic organic resins serve to encapsulate these mounting members such as electrodes and metal members, to give the effect of filling in unevenness in the element surface and smoothing the surface of the covering material.

However, it has been revealed that contrary to expectation, the surface of conventional solar cell modules covered with a fluoride polymer film is susceptible to staining. The reasons are considered to be such that: 1) it is hard for rainwater to wet the surface of the modules because of the strong water repellency of the fluoride polymer film, thereby hard to wash away stains having adhered to the surface of the modules; and 2) rainwater remains on the surface of the modules in the form of droplets, and once the droplets of rainwater are dried, stains such as dust contained in the rainwater is concentrated and speckles the surface of the modules.

Attempts have been made to overcome the above problems. For example, Japanese Patent Application Laid-Open Nos. H09-83005 and 2000-31509 disclose that a film whose surface is provided with a photocatalytic layer of, for example, titanium oxide is used as the front surface member of a solar cell module to decompose stains on the surface of the module through a photocatalytic action of the layer, and besides, the surface of the film is made ultra-hydrophilic to allow rainwater to easily wash away stains deposited to the surface so that the lowering in output due to stains is suppressed. In this case, however, there still remain problems that the photocatalytic layer also decomposes the film as a substrate, the photocatalytic layer peels off from the film, and that providing the photocatalytic layer is costly, and thus the proposals are hard to employ.

Further, there have been proposed in Japanese Patent Application Laid-Open Nos. 2001-177130 and 2002-270866 that a film containing organosilicate is provided on the surface of a solar cell module or a stain-resistant agent that contains silicone oil as a major component is applied to the surface of a solar cell module, whereby the resistance to stains is improved. However, it is hard to realize such proposals, because such a stain-resistant film or agent is poor in adhesion to a fluoride polymer film, as a result, even if the film or agent is applied to the fluoride polymer film, sufficient durability is not obtained, and moreover, such stain-resistant treatment is costly.

Moreover, there has been also proposed in Japanese Patent Application Laid-Open Nos. H11-298030 and 2001-358346 that a cover glass for solar cells is used whose light incidence surface is provided with a specified surface roughness so that the roughness makes it hard for stains to remain on the surface. However, providing such a surface unevenness texture on the surface of a fluoride polymer film, does not give the desired effect.

### SUMMARY OF THE INVENTION

The present invention has been accomplished in the light of the above situation and therefore in order to fill the demand for provision of a solar cell module that is hard to stain even when placed outdoors for a long period of time and consequently capable of suppressing lowering in output caused by a decrease in quantity of incident light resulting from staining of the module surface, at a low cost.

According to the present invention, there is provided a solar cell module comprising a solar cell element, and a front surface member provided so as to cover a light incidence surface of the solar cell element to provide an outermost surface of the solar cell module, wherein the front surface member comprises a fluoride polymer film having a light incidence surface subjected to a discharge treatment.

The present invention makes it possible to provide a solar cell module at a low cost, which is hard to stain even when placed outdoors for a long period of time and consequently capable of suppressing the lowering in output caused by the decrease in quantity of incident light resulting from staining.

In the present invention, when the discharge treatment is effected in a mixed gas comprising an inert gas and carbon dioxide gas, the stain resistance effect can be maintained for a long period of time.

Further, when an unevenness texture is formed in the light incidence surface of the fluoride polymer film, it is possible to further suppress the staining.

Moreover, when the unevenness texture has an arithmetic mean height Ra of 0.5 to 3 μm and a maximum height Rz of 5 to 20 μm, the stain resistance and the glare protection are allowed to be compatible with each other.

Moreover, when the light incidence surface of the fluoride polymer film has a contact angle with water of 75° to 95°, the stain resistance can be developed without reducing the mechanical strength of the surface member film.

Further, when the fluoride polymer is ethylene-tetrafluoroethylene copolymer, the discharge treatment can produce a great stain-resistance effect.

Moreover, with a solar cell module array comprising the above-mentioned solar cell module in plurality, when the solar cell modules are placed at an inclination of 20° or less, it is possible to remarkably reduce the significant lowering in output due to staining, which has been caused in conventional solar cell arrays where the conventional solar cell modules are placed at an inclination of 20° or less.

Other features and advantages of the present invention will be apparent from the following description taken in conjunction with the accompanying drawings.

### BRIEF DESCRIPTION OF THE DRAWINGS

FIG. 1A is a schematic plan view showing an embodiment of the solar cell module in accordance with the present invention, and FIG. 1B is a schematic sectional view taken on line 1B-1B in FIG. 1A;

FIG. 2A is a schematic plan view showing a solar cell module of Example 1, and FIG. 2B is a schematic sectional view taken on line 2B-2B in FIG. 2A; and

FIG. 3 is an enlarged view showing a portion of the solar cell module of FIGS. 2A and 2B to which a diode is attached.

### DESCRIPTION OF THE PREFERRED EMBODIMENTS

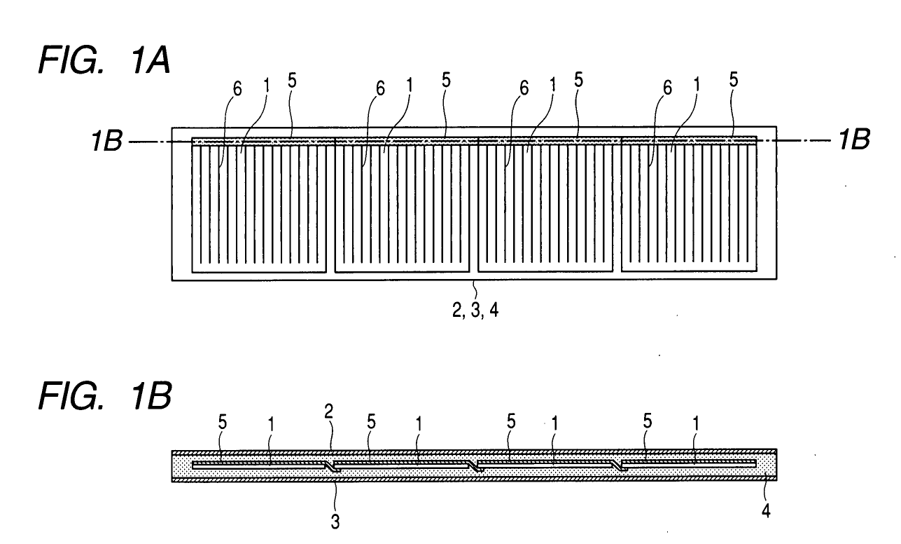

FIGS. 1A and 1B are schematic structural views of a solar cell module in accordance with the present invention. In the figures, reference numeral 1 denotes a solar cell element, numeral 2 a front surface member made of a fluoride polymer film and provided on the light-receiving surface side of the solar cell element 1, numeral 3 a rear surface member provided on the non-light-receiving surface side of the solar cell element 1, numeral 4 an encapsulating material provided inside the front surface member 2 and the rear surface member 3, numeral 5 a bus bar electrode, and numeral 6 a current collecting electrode. A light from outside enters the front surface member 2 that provides the outermost surface of the solar cell module and reaches the solar cell elements 1, and a photovoltaic force as generated is taken outside through output terminals (not shown).

The fluoride polymer film as the front surface member 2 of the present invention is not particularly limited to any specific one, as long as it is a polymer film containing fluorine as its constituent. Examples of fluoride polymer include polyvinylidene fluoride (PVDF), polyvinyl fluoride (PVF), ethylene-tetrafluoroethylene copolymer (ETFE), polychlorotrifluoroethylene (PCTFE), chlorotrifluoroethylene-ethylene copolymer (ECTFE), perfluoro(alkyl vinyl ether)-tetrafluoroethylene copolymer (PFA), hexafluoropropylene-tetrafluoroethylene copolymer (FEP), tetrafluoroethylene-hexafluoropropylene-vinylidene fluoride copolymer, and the mixtures of the two or more thereof. Of the above fluoride polymers, ETFE is preferably used because it is excellently suitable for the front surface member of the solar cell module from the viewpoint of compatibility between weather resistance and mechanical strength as well as transparency. Another reason for selecting ETFE is that ETFE is easy to produce a reactant on a film thereof when subjected to discharge treatment.

The copolymers, such as ETFE, used in the present invention include those of other copolymerizable monomers. Examples of other copolymerizable monomers are other fluoroolefins, other olefins and vinyl monomers.

In the present invention, the light incidence surface of the front surface member 2 is subjected to a discharge treatment. The discharge treatment applicable includes, for example, a corona discharge treatment, a plasma discharge treatment, a glow discharge treatment, and the like. In any treatment, a treating surface of the film is exposed to a gas atmosphere and treated with a corona discharge, plasma discharge or glow discharge generated by applying a high-frequency voltage between electrodes.

As the atmospheric gas used in the discharge treatment, there are preferably used two or more gases selected from the group consisting of oxygen, nitrogen, carbon dioxide, a gas of a reactive compound having C═O bond such as acetone gas, an inert gas such as helium, neon, argon, krypton, xenon or radon gases, and a gas of a polymerizable unsaturated compound having a double bond such as ethylene or propylene gas. Particularly, a mixed gas that contains at least an inert gas and carbon dioxide is more preferably used because it improves the durability of reactants produced on the film surface and maintains the effect of the treatment for a long period of time even when exposed to the outdoors.

Further, it is preferable that the discharge treatment is carried out such that the contact angle with water of the surface of the front surface member 2 is 75° to 95°. If the contact angle is more than 95°, the effect of the treatment might not be fully produced, whereas if the contact angle is less than 75°, the treated layer becomes too thick, which might cause a problem of lowering in mechanical strength of the film.

Moreover, it is preferable that the light incidence surface of the front surface member 2 is provided with an unevenness texture. The unevenness texture is provided preferably prior to the discharge treatment. Processes applicable to providing the unevenness texture include, for example, 1) a process which is carried out, in a film extrusion process and after extruding molten fluoride polymer through a slit, by pressing a cooling roll having an irregular unevenness pattern formed on its surface onto the extruded film to transfer the unevenness texture from the roll to the film, and 2) a sandblasting process.

The shape of the unevenness texture is preferably such that the arithmetic mean height Ra is 0.5 to 3 μm and the maximum height Rz is 5 to 20 μm, because such an unevenness texture allows glare protection and stain resistance to be compatible with each other at a high level. If Ra is less than 0.5 μm or more than 3.0 μm, the glare protection become insufficient, and besides, the reflection loss on the light incidence surface becomes large in the morning and evening when the incident angle of sunlight is small, which might reduce the quantity of electricity generated by solar cell modules. On the other hand, if Rz is less than 5 μm, the stain resistance might not be sufficiently improved, whereas if Rz is more than 20 μm, dusts might be more likely to remain at the bottom portion of the unevenness.

Providing the front surface member 2 with an unevenness texture makes unnecessary the use of an embossing member, which has been used in lamination of conventional solar cell modules. The surface of the embossing member requires periodic maintenance because an encapsulating material flowing out during the lamination may sometimes adhere to the surface; however, providing the front surface member 2 with an unevenness texture saves such time and labor.

When the unevenness texture is provided in both the front and the rear surfaces of the front surface member 2, it is preferable that there is no correlation between the textures of the front and the rear surfaces of the front surface member 2. The reason is that the glare protection is enhanced if there is no correlation therebetween. Alternatively, the unevenness texture may be provided only in the front surface of the front surface member 2 with the rear surface being specular.

In the following each of the members that constitute the solar cell module will be described.

As the solar cell element 1, any one of conventionally known elements, such as crystalline silicon solar cells, polycrystalline silicon solar cells, microcrystalline silicon solar cells, amorphous silicon solar cells, copper indium selenide solar cells and compound semiconductor solar cells, can be selected and used depending on the objective. A plurality of the thus selected solar cell elements are connected in series or in parallel depending on the desired voltage or current. Apart from this, solar cell elements may be integrated on an insulated substrate to obtain a desired voltage or current. Further, to prevent application of a backward bias voltage to the elements, bypass diodes may be connected to the elements as the need arises.

The encapsulating material 4 is used for covering the solar cell elements 1 to protect the elements against severe external environment such as temperature change, humidity and impact, and at the same time, ensure the adhesion of the front surface member 2 or the rear surface member 3 to the elements. Examples of such materials include ethylene-vinyl acetate copolymer (EVA) resin, ethylene-methyl acrylate copolymer (EMA) resin, ethylene-ethyl acrylate (EEA) resin, ethylene-methacrylic acid (EMAA) resin, ionomer resin, and polyvinyl butyral resin. Of the above materials, EVA resin is preferably used because it has well-balanced physical properties for solar cell use, such as weather resistance, adhesion, filling properties, heat resistance, low-temperature resistance and impact resistance. However, the EVA resin as such undergoes thermal deformation at low temperatures and thus it easily deforms or creeps under high temperature use conditions; accordingly, it is preferable to crosslink the resin to improve the heat resistance beforehand.

The rear surface member 3 is used to protect the solar cell elements 1, prevent moisture from intruding into the solar cell module, and keep the module electrically insulated from the outside. As its material are preferable those that ensure sufficient electrical insulation, excel in long-term durability, and resist thermal expansion and thermal shrinkage. Examples of preferably used materials are polyvinyl fluoride film, nylon film, polyethylene terephthalate film and glass sheet.

A reinforcing plate for the purpose of mechanical reinforcement may further be adhered to the outside of the rear surface member 3. Such reinforcing plates include, for example, plates of metal, fiber reinforced plastic (FRP) and ceramic. In the solar cell module integrated with a building material, the building material may also serve as this reinforcing plate.

Then, the process will be described of producing a solar cell module using the above mentioned front surface member 2, solar cell elements 1, encapsulating material 4 and rear surface member 3.

First, the encapsulating material 4 having been formed into a sheet is placed on both sides of the solar cell elements 1 and the front surface member 2 and the rear surface member 3 are placed on the light incidence surface and the rear surface, respectively, to form a stack. A solar cell module can be produced by heat pressing this stack in a vacuum using a vacuum laminator. A solar cell module can also be produced by means of roll lamination.

When placing the solar cell modules of the present invention on an outdoor stand to form a solar cell array thereon, it is preferable that the inclination of the module placed is 20° or less. The reason is that when the inclination is 20° or less, the light incidence surface of the solar cell module is susceptible to staining, and therefore, working the present invention in that situation is significantly effective in preventing such staining. Thus, if the solar cell modules of the present invention are applied to a solar cell module array that is placed at a low inclination, for example, those placed on a stand of a low profile or those placed on a stand in a low latitude region, a large effect can be expected.

In the following the present invention will be described in detail taking a few examples.

### EXAMPLE 1

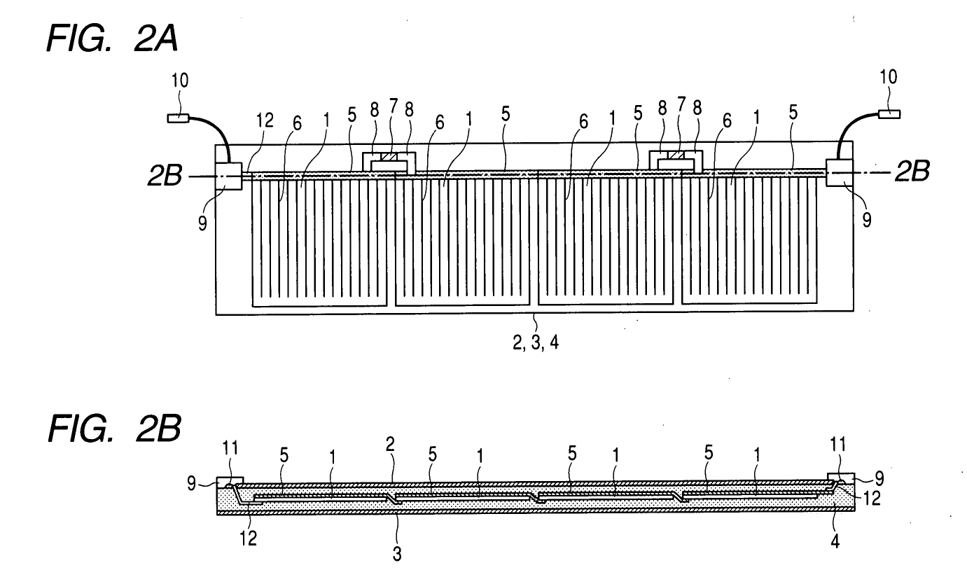

In the following, a process will be described with reference to FIGS. 2A and 2B for producing a solar cell module in accordance with the first example of the present invention which uses amorphous silicon solar cells (solar cell elements) each prepared by forming successively on a conductive substrate, a rear surface reflection layer, an optically active semiconductor layer and a transparent electrode layer and providing a comb-shape current collecting electrode and a bus bar electrode connected thereto on the transparent electrode.

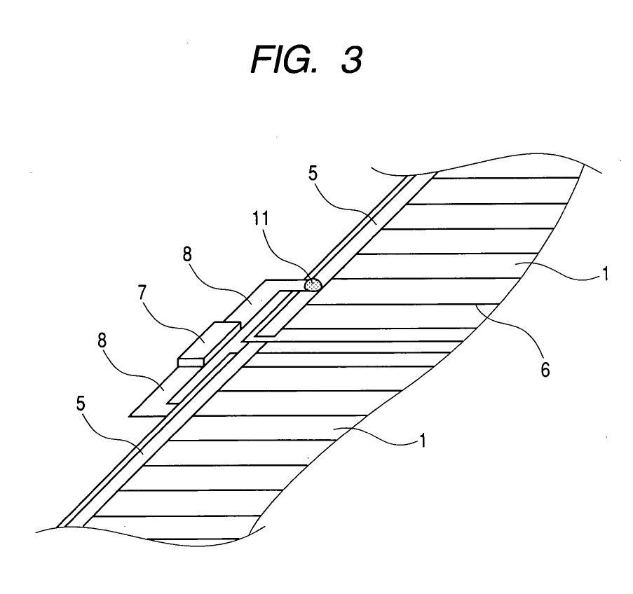

A plurality of solar cell elements 1 are connected in series, and output take-out electrodes 12 formed of a copper foil are attached to a bus bar electrode 5 provided on the solar cell element at one end of the series of solar cell elements and to the conductive substrate of the solar cell element at the other end of the series of solar cell elements, respectively. Further, to prevent the application of a backward bias voltage to the elements, bypass diodes 7 are attached to the solar cell elements using copper foils 8. The bypass diodes 7 are connected to the respective elements or the respective groups of a plurality of in-series elements in a parallel fashion. In this example, one diode 7 is attached to each group of two solar cell elements 1 connected in series. FIG. 3 is an enlarged view showing a portion of the solar cell module to which the diode 7 is attached, in which figure copper foil 8 connected to the bypass diode 7 is connected to the bus bar electrodes 5 of one element and the conductive substrates as a counter electrode to the bus bar electrodes 5 of the other element of the two adjacent solar cell elements 1. In this example, Schottky-barrier diodes of thin/small package for surface mount are used as the bypass diodes 7, taking into consideration the encapsulating properties of the encapsulating material 4 described later.

Then, the covering material for encapsulating the series of solar cell elements will be described.

As the front surface member 2, there is used an ethylene-tetrafluoroethylene copolymer (ETFE) film of an average thickness of 25 μm having an unevenness texture provided on both surfaces thereof. The unevenness texture is provided by passing the film right after the extrusion between embossing rollers. The thus provided unevenness texture has an arithmetic mean height Ra of 1.4 to 2.0 μm and a maximum height Rz of 8 to 13 μm.

The both surfaces of the film each provided with the unevenness texture are subjected to a discharge treatment in a mixed gas containing argon gas and carbon dioxide gas. As a result of the discharge treatment, the contact angle with water of the film surfaces becomes about 80°.

Then, on a polyester film of 100 μm in thickness which is used as the rear surface member 3, a sheet of EVA resin of 0.4 mm in thickness as an encapsulating material for solar cells (encapsulating material 4), in-series solar cell elements, a sheet of EVA resin of 0.4 mm in thickness (encapsulating material 4) and the above-mentioned ETFE film (front surface member 2) are stacked successively, and the stack is heat pressed with a vacuum laminator to encapsulate the solar cell elements.

The EVA resin sheet used in this example is widely used as an encapsulating material for solar cells and is obtained by blending with 100 parts by weight of EVA resin (vinyl acetate content: 33 wt %), 1.5 parts by weight of a crosslinking agent, 0.3 part by weight of an ultraviolet light absorber, 0.1 part by weight of a light stabilizer, 0.2 part by weight of an antioxidant and 0.25 part by weight of a silane coupling agent.

The output take-out electrodes 12 are led out through the openings provided in advance in the EVA resin sheet (encapsulating material 4) and the ETFE film (front surface member 2) and connected to cables 10. The connected portions are housed in terminal boxes 9, respectively and the terminal boxes are sealed with a silicone sealant or the like to ensure their watertightness.

The solar cell module produced by the above process was subjected to an outdoor exposure test while placing them at an inclination of 15°, and their electric characteristics after 2 weeks, 1 month and 2 months were measured using a solar simulator. The values of output and short-circuit current measured after 2 weeks, 1 month and 2 months as normalized with the values before test being defined as 1 are shown in Table 1. The number of samples tested is 10 and the data shown in the table are average values thereof.

### EXAMPLE 2

Solar cell modules were produced following the same procedure as in Example 1 with the exception that the front surface member was not provided with an unevenness texture, and evaluation was made in the same manner as in Example 1. The results are shown in Table 1.

### COMPARATIVE EXAMPLE 1

Solar cell modules were produced following the same procedure as in Example 1 with the exception that the front surface member was not provided with an unevenness texture and the light incidence surface thereof was not subjected to a discharge treatment, and evaluation was made in the same manner as in Example 1. The results are shown in Table 1.

TABLE 1

| | After 2 weeks | | After 1 month | | After 2 months | |
|---|---|---|---|---|---|---|
| | | Short- | | Short- | | Short- |
| | | circuit | | circuit | | circuit |
| | Output | current | Output | current | Output | current |
| Example 1 | 0.920 | 0.980 | 0.903 | 0.960 | 0.889 | 0.955 |
| Example 2 | 0.911 | 0.972 | 0.893 | 0.953 | 0.875 | 0.943 |
| Comparative | 0.910 | 0.969 | 0.890 | 0.948 | 0.870 | 0.933 |
| Example 1 | | | | | | |

As is apparent from Table 1, in the solar cell modules of Example 1 and Example 2, the lowering in output in the outdoor exposure test was small compared with that of the solar cell modules of Comparative Example 1. Further, the lowering was smaller particularly in the solar cell modules of Example 1. The same applies to the short-circuit current. These results have clarified that the suppression of the lowering in short-circuit current is related to the suppression of the lowering in module output. Further, it is presumed that the suppression of the lowering in short-circuit current means that the quantity of light entering the solar cell elements is hard to decrease. The observation of the module surfaces revealed that the light incidence surface of each module was stained with a thin coat of dust, but the degree of staining was smallest in the modules of Example 1 and it became larger in the modules of Example 2 and Comparative Example 1 in this order. This indicates that discharge-treating the light incidence surface of the front surface member can suppress staining of the surface, thereby providing solar cell modules whose output is less lowered even when exposed to the outdoors. The comparison between the modules of Example 1 and Example 2 further revealed that providing the light incidence surfaces of the front surface members with a specified unevenness texture produced much more effect of preventing staining of the surfaces.

It should be understood that the above examples are not intended to limit the solar cell module of the present invention, and various changes and modifications can be made in the invention without departing the spirit and the scope thereof.

As described so far, according to the present invention, by employing the front surface member comprising a fluoride polymer film having a light incidence surface subjected to a discharge treatment, the solar cell module becomes difficult to stain even when placed outdoors for a long period of time, with the result that the lowering in output caused in solar cell modules having surfaces coated with a fluoride polymer film by the reduction in quantity of incident light due to staining, can be suppressed at a low cost.

Further, according to the present invention, by forming an unevenness texture having an arithmetic mean height Ra of 0.5 to 3 μm and a maximum height Rz of 5 to 20 μm in the light incidence surface of the front surface member, it becomes possible to attain the effect of enhancing the glare protection and reducing the reflection loss in the morning and evening while enhancing the stain resistance.

Further, according to the present invention, with a solar cell module array comprising the above-mentioned solar cell module in plurality, when the solar cell modules are placed at an inclination of 20° or less, it is possible to remarkably reduce the significant lowering in output due to staining, which has been caused in conventional solar cell arrays where the conventional solar cell modules are placed at an inclination of 20° or less.

What is claimed is:

1. A solar cell module comprising
a solar cell element, and a front surface member provided so as to cover a light incidence surface of the solar cell element to provide an outermost surface of the solar cell module,
wherein the front surface member comprises a fluoride polymer film having a light incidence surface subjected to a discharge treatment.

2. The solar cell module according to claim 1, wherein the discharge treatment is effected in a mixed gas comprising an inert gas and carbon dioxide gas.

3. The solar cell module according to claim 1, wherein an unevenness texture is formed in the light incidence surface of the fluoride polymer film.

4. The solar cell module according to claim 3, wherein the unevenness texture has an arithmetic mean height Ra of 0.5 to 3 μm and a maximum height Rz of 5 to 20 μm.

5. The solar cell module according to claim 1, wherein the light incidence surface of the fluoride polymer film has a contact angle with water of 75° to 95°.

6. The solar cell module according to claim 1, wherein the fluoride polymer is ethylene-tetrafluoroethylene copolymer.

7. A solar cell module array comprising the solar cell module set forth in claim 1 in plurality, wherein the solar cell modules are placed at an inclination of 20° or less.
